(19) United States
(12) Patent Application Publication
(10) Pub. No.: US 2026/0280420 A1
(43) Pub. Date: Sep. 17, 2026

(54) POWER CONVERTER WITH CAPACITOR EMBEDDED CONNECTOR

(71) Applicant: Monolithic Power Systems, Inc., Kirkland, WA (US)

(72) Inventors: Ting GE, San Jose, CA (US); Yingjiang PU, Chengdu (CN); Eric NGUYEN, Bellevue, WA (US)

(21) Appl. No.: 19/077,868

(22) Filed: Mar. 12, 2025

(51) Int. Cl. H02M 3/00; H05K 1/11; H05K 1/18

(52) U.S. Cl. CPC H02M 3/003; H05K 1/111; H05K 1/181; H05K 2201/1003

(57) ABSTRACT

A power converter has an inductor unit disposed on a base substrate, and a connector vertically disposed on the base substrate. The inductor unit has an output inductor electrically connected to a switch node formed by a pair of switches. The connector has a substrate which is perpendicular to the base substrate, and a plurality of capacitors attached to the substrate.

### BACKGROUND OF THE INVENTION

### 1. Field of the Invention

The present invention relates generally to electrical circuits, and more particularly but not exclusively to power converters.

### 2. Description of Related Art

Power converter, as known in the art, converts an input power to an output power for providing a load with required voltage and current. Multi-phase power converter comprising a plurality of paralleled power stages operating out of phase has lower output ripple voltage, better transient performance and lower ripple-current-rating requirements for input capacitors. They are widely used in high current and low voltage applications, such as server, microprocessor, AI and so on.

With the development of modern GPUs (Graphics Processing Units), and CPUs (Central Processing Units), increasingly high load current is required to achieve better processor performance. Besides, to improve integration density of the terminal products like CPUs and GPUs, the size of their power converters needs to be smaller.

### SUMMARY OF THE INVENTION

Embodiments of the present invention are directed to a power converter having a first power die and a second power die, an inductor unit disposed on a base substrate, and a first connector vertically disposed on the base substrate. Each of the first and second power die has a gate driver and a pair of switches. The inductor unit has a first output inductor and a second output inductor. The first output inductor is electrically connected to a switch node formed by the pair of switches of the first power die. The second output inductor is electrically connected to a switch node formed by the pair of switches of the second power die. The first connector comprising a first substrate, and a first plurality of capacitors attached to a planar side of the first substrate.

Embodiments of the present invention are directed to a power module having a base substrate, a first pair of switches and a second pair of switches, a first inductor unit disposed on the base substrate, a top substrate disposed on the first inductor unit, and a first connector and a second connector vertically disposed between the base substrate and the top substrate. The first inductor unit has a magnetic core, a first winding and a second winding embedded in the magnetic core. The first winding is electrically connected to a first switch node formed by the first pair of switches. The second winding is electrically connected to a second switch node formed by the second pair of switches. Each of the first and second connectors has a substrate, and a first plurality of capacitors attached to the substrate.

Embodiments of the present invention are directed to a power converter operable to provide an output voltage to a load which is disposed on a first side of a motherboard. The power converter has an inductor unit disposed on a second side of the motherboard, which is opposite to the first side of the motherboard. The converter further has a first connector vertically disposed on the second side of the motherboard. The inductor unit has an output inductor electrically connected to a switch node formed by a pair of switches. The first connector comprises a first substrate which is perpendicular to the base substrate, and a first plurality of capacitors attached to the first substrate.

These and other features of the present invention will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The drawings are not necessarily to scale.

FIG. 1 shows an electrical schematic diagram of a power converter 100 in accordance with an embodiment of the present invention.

FIG. 2 shows a side view of a physical layout of a power converter 200 in accordance with an embodiment of the present invention.

FIG. 3A shows a capacitor embedded connector 22 of the power converter 200 of FIG. 2 in accordance with an embodiment of the present invention.

FIG. 3B shows the capacitor embedded connector 22 of the power converter 200 of FIG. 2 in accordance with another embodiment of the present invention.

FIG. 4 shows a planar side view of the capacitor embedded connector 22 in accordance with an embodiment of the present invention.

FIG. 5 shows the planar side view of the capacitor embedded connector 22 in accordance with another embodiment of the present invention.

FIG. 6 shows a layout of a substrate 210 of the capacitor embedded connector 22 in accordance with an embodiment of the present invention.

FIG. 7 shows a planar view of a top surface 321 of an inductor unit 202 in accordance with an embodiment of the present invention.

FIG. 8 shows a planar view of a bottom surface 322 of the inductor unit 202 in accordance with an embodiment of the present invention.

FIG. 9 shows a side view of a physical layout of a power converter 200A in accordance with an embodiment of the present invention.

FIG. 10 shows a transparent three-dimensional (3D) view of a power module 300 in accordance with an embodiment of the present invention.

FIG. 11 shows a transparent 3D view of the capacitor embedded connector 22 of the power module 300 in accordance with an embodiment of the present invention.

FIG. 12 shows a 3D transparent view of an inductor unit 202A, in accordance with an embodiment of the present invention.

FIG. 13 shows additional 3D transparent view of the inductor unit 202A, in accordance with an embodiment of the present invention.

FIG. 14 shows a side view of a physical layout of a power converter 200B in accordance with an embodiment of the present invention.

FIG. 15 shows a side view of a physical layout of a power converter 200C in accordance with an embodiment of the present invention.

FIG. 16 shows a side view of a physical layout of a power converter 200D in accordance with an embodiment of the present invention.

FIG. 17 shows a side view of a physical layout of a power supply system 400 in accordance with an embodiment of the present invention.

### DETAILED DESCRIPTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Power modules must deliver increasingly higher current densities to meet the escalating power demands of central processing units (CPUs), graphics processing units (GPUs), and other components used in artificial intelligence (AI) applications. One of industry trends is to place the power module on a backside of a motherboard to provide shorter power delivery network, wherein a load (e.g., the CPU or GPU) is placed on a topside of the motherboard. The active devices and capacitors then need to share the space beneath the load. Inductors and dies of power switches typically occupy most of the area of a power module. Inductors and dies of power switches may be stacked to increase current density, such as in sandwich or inductor-on-top configuration. Embodiments of the present further increase current density by vertically installing the capacitors.

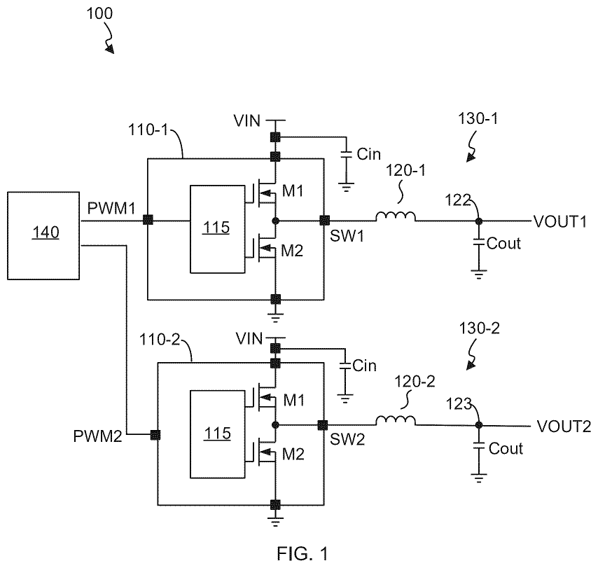

FIG. 1 shows an electrical schematic diagram of a power converter 100, in accordance with an embodiment of the present invention.

In the example of FIG. 1, the power converter 100 has two regulator circuits 130 (i.e., 130-1, 130-2), with each regulator circuit 130 comprising an output inductor 120 (i.e., 120-1, 120-2) and a power stage 110 (i.e., 110-1, 110-2). As will be more apparent below, the power stage 110 may be formed in an integrated circuit (IC) die, which is referred to herein as a power die. One or more regulator circuits 130 may be implemented as a power module, including one or more power dies and a plurality of inductors 120 which share a same magnetic core. So that the power converter 100 could have a compact size.

In the example of FIG. 1, each regulator circuit 130 is configured such that the power converter 100 is a buck converter. As can be appreciated, each regulator circuit 130 may also be configured such that the power converter 100 is a boost converter or other type of power converter depending on the application. Each of the regulator circuits 130-1 and 130-2 receives an input voltage VIN to generate an output voltage VOUT (i.e., VOUT1, VOUT2). The output voltages of the regulator circuits 130-1 and 130-2 may be connected together and interleaved to generate a multiphase output voltage. For example, an output voltage node 122 of the regulator circuit 130-1 and an output voltage node 123 of the regulator circuit 130-2 may be connected together, with each regulator circuit 130 generating a phase of the power converter 100. Generally, the power converter 100 may include additional regulator circuits 130 to generate additional phases of a multiphase output voltage or additional separate output voltages. The power converter 100 may also be configured as a single-phase converter by utilizing a single regulator circuit 130.

In the example of FIG. 1, each power stage 110 has a driver 115, a high-side switch M1, and a low-side switch M2. In one embodiment, the switches M1 and M2 are metal oxide semiconductor field effect switches (MOSFETs) and the driver 115 is a gate driver that is integrated with the MOSFETs M1 and M2. In the example of FIG. 1, each power stage 110 has a first node for receiving a PWM signal (PWM1, PWM2), a second node for receiving an input voltage VIN, a third node for connecting to ground, and a switch node SW (SW1, SW2) formed by the pair of switches M1 and M2. The drain of the switch M1 is connected to the input voltage VIN and the source of the switch M2 is connected to ground. The source of the switch M1 is connected to the drain of the switch M2 at the switch node SW. A PWM controller 140 generates PWM signals (PWM1, PWM2). The driver 115 turns the switches M1 and M2 ON and OFF in accordance with a corresponding PWM signal to generate the output voltage VOUT.

In the example of FIG. 1, a first end of an output inductor 120 is electrically connected to the switch node SW and a second end of the output inductor 120 is electrically connected to the output voltage VOUT. Two or more output inductors 120 may be formed by two or more inductor windings that share the same magnetic core. An input capacitor Cin is connected to the input voltage VIN, and an output capacitor Cout is connected to the output voltage VOUT. Each of the input capacitor Cin and output capacitor Cout may comprise a plurality of capacitors that are connected in parallel. The power converter 100 may be implemented by using one or more capacitor embedded connectors that each includes a plurality of capacitors (e.g., a plurality of input capacitors Cin and a plurality of output capacitors Cout).

In one embodiment, each power stage may be implemented as a single power die. In another embodiment, more than one power stages may be integrated together in a single power die. One or more capacitor embedded connectors may be placed out of a power module, or be incorporated into the power module, depending on different applications.

A controller (e.g., FIG. 1, PWM controller 140) may be installed on a motherboard or other substrates that are external to the power module. In one embodiment, the capacitor embedded connectors may be vertically installed on the motherboard or other substrates that are external to the power module. In another embodiment, the capacitor embedded connectors may be integrated in the power module and be vertically installed to connect a top substrate and a base substrate of the power module.

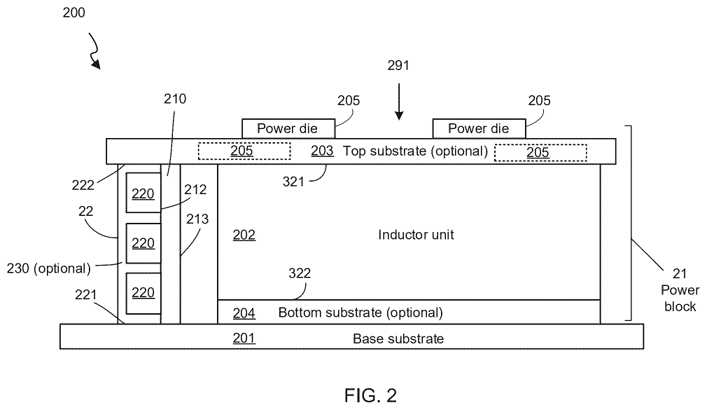

FIG. 2 shows a side view of a physical layout of a power converter 200 in accordance with an embodiment of the present invention. FIG. 2 is not drawn to scale. The power converter 200 may comprise the power converter 100 of FIG. 1 or other power converter. As used herein, the term “physical layout” refers to a schematic representation of the arrangement of components and is not intended to represent precise physical dimensions or proportions. The term “edge” refers to narrower sides, in contrast to planar sides, which have a significantly larger surface area. FIG. 2 shows a side edge of a capacitor embedded connector 22. The capacitor embedded connector 22 shown in FIG. 2 includes three capacitors in a vertical direction as one example, more or less capacitors may also be included for different applications.

The power converter 200 comprises a base substrate 201, a power block 21 disposed on the base substrate 201, and the capacitor embedded connector 22 vertically disposed on the base substrate 201, e.g., a bottom edge 221 of the capacitor embedded connector 22 is attached to the base substrate 201. In one embodiment, the base substrate 201 is the motherboard, the power block 21, the capacitor embedded connector 22, the controller 140, and other components may be installed on the motherboard. In another embodiment, the power converter 200 is a power module including the base substrate 201, the power block 21, and capacitor embedded connector 22.

As one example, the base substrate 201 is a printed circuit board (PCB). The power block 21 is disposed on the base substrate 201, and includes one or more power dies 205 (e.g., each power die 205 including a gate driver 115 and a pair of switches M1 and M2 as shown in FIG. 1) and an inductor unit 202 (e.g., including one or more output inductors 120 as shown in FIG. 1). A single power die 205 may thus generate a single phase of an output voltage. Adding more power dies 205 allows the power converter 200 to generate additional output voltage phases.

The inductor unit 202 has a top surface 321 and a bottom surface 322. FIG. 2 shows a reference arrow 291 pointing to the bottom surface 322 of the inductor unit 202 from top. Each of the output inductors of the inductor unit 202 is electrically connected to a switch node formed by a corresponding pair of switches. One or more power dies 205 may be disposed above or below the inductor unit 202. The power block 21 may optionally include a top substrate 203 disposed at a top end of the power block 21 and facing towards the base substrate 201, the power die 205 may be embedded in or disposed on a top side of the top substrate 203. In one example, the capacitor embedded connector 22 vertically connects the top substrate 202 to the base substrate 201, e.g., the bottom edge 221 of the capacitor embedded connector 22 is attached to the base substrate 201, the top edge 222 of the capacitor embedded connector 22 is attached to a bottom side of the top substrate 203. Nodes on the top substrate 202 are electrically connected to corresponding nodes on the base substrate 201 via the capacitor embedded connector 22. In another example, the power block 21 may optionally include a bottom substrate 204 disposed between the inductor unit 202 and the base substrate 201. One or more power dies 205 may be embedded in or disposed on a top side of the bottom substrate 204.

The capacitor embedded connector 22 includes a plurality of capacitors 220, including output capacitors Cout and/or input capacitors Cin. In the example of FIG. 2, The capacitor embedded connector 22 has a substrate 210, the plurality of capacitors 220 are attached to a first planar side 212 of the substrate 210, e.g., via soldering. A second planar side 213, which is opposite to the first planar side 212 of the substrate 210, faces towards the inductor unit 202. The first planar side 212 and the second planar side 213 are perpendicular to the base substrate 201. In one example, empty regions in the capacitor embedded connector 22 are filled with molding compound 230, which is optional.

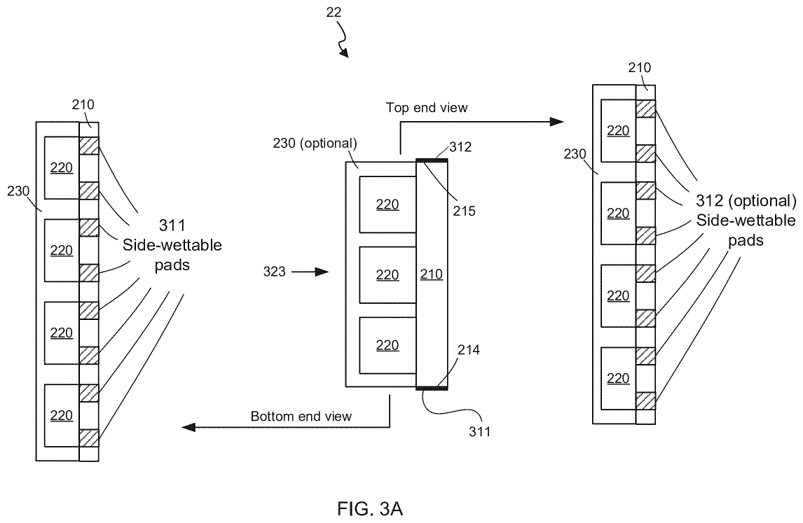

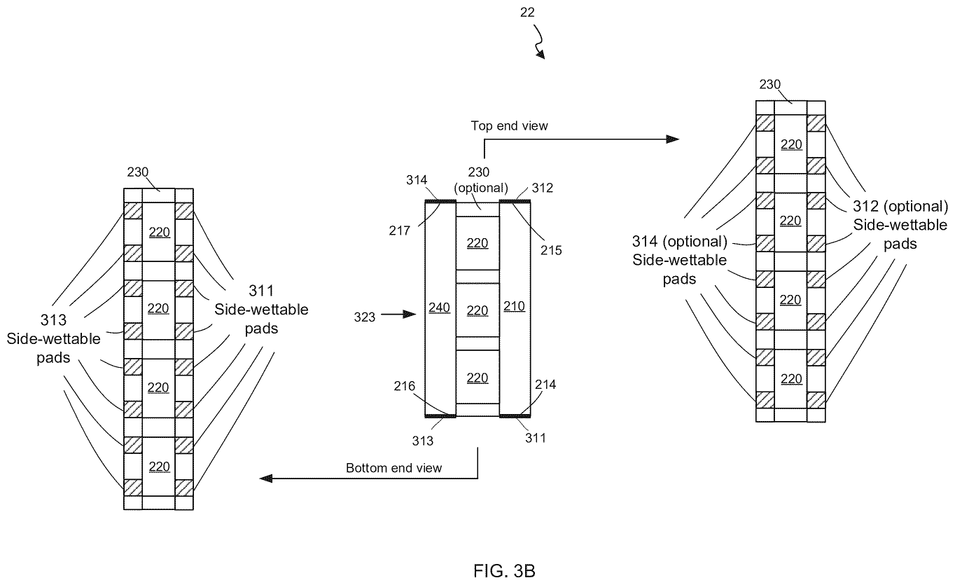

FIG. 3A shows the capacitor embedded connector 22 of the power converter 200 of FIG. 2 in accordance with an embodiment of the present invention.

The substrate 210 of the capacitor embedded connector 22 has a bottom edge 214 and a top edge 215. The bottom edge 214 is attached to the base substrate 201 (not shown in FIG. 3A, referring FIG. 2), for example, via side-wettable pads 311. The side-wettable pads 311 could be soldered to the base substrate 201, to provide electrically connection between the capacitor embedded connector 22 and nodes on the base substrate 201. Optionally, the top edge 215 is attached to the top substrate 203 (not shown in FIG. 3A, referring FIG. 2), for example, via side-wettable pads 312. The side-wettable pads 312 could be soldered to the bottom side of the top substrate 203, to provide electrically connection between the capacitor embedded connector 22 and nodes on the top substrate 203.

FIG. 3A also shows a top end view of the capacitor embedded connector 22 (see right side of FIG. 3A) and a bottom end view of the capacitor embedded connector 22 (see left side of FIG. 3A). In the example of FIG. 3A, the capacitor embedded connector 22 includes four capacitors in the top end and the bottom end views. In other examples, more or less capacitors may be included, not limited by FIG. 3A. A reference arrow 323 points to a planar side of the capacitor embedded connector 22.

FIG. 3B shows the capacitor embedded connector 22 of the power converter 200 of FIG. 2 in accordance with another embodiment of the present invention.

In the embodiment of FIG. 3B, the capacitor embedded connector 22 further has a substrate 240. The capacitors 220 are soldered between two substrates 210 and 240. The substrate 240 has a first planar side which the capacitors 220 are attached to, and a second planar side opposite to the first planar side. The first and second planar sides of the substrate 240 are perpendicular to the base substrate 201 (see FIG. 2).

The substrate 240 of the capacitor embedded connector 22 has a bottom edge 216 and a top edge 217. The bottom edge 216 is attached to the base substrate 201 (not shown in FIG. 3A, referring FIG. 2), for example, via side-wettable pads 313. The side-wettable pads 313 could be soldered to the base substrate 201, to provide electrically connection between the capacitor embedded connector 22 and nodes on the base substrate 201. Optionally, the top edge 217 is attached to the top substrate 203 (not shown in FIG. 3A, referring FIG. 2), for example, via side-wettable pads 314. The side-wettable pads 314 could be soldered to the bottom side of the top substrate 203, to provide electrically connection between the capacitor embedded connector 22 and nodes on the top substrate 203.

FIG. 3B also shows a top end view (see right side of FIG. 3B) and a bottom end view (see left side of FIG. 3B) of the capacitor embedded connector 22. The reference arrow 323 points to the planar side of the capacitor embedded connector 22 of FIG. 3B.

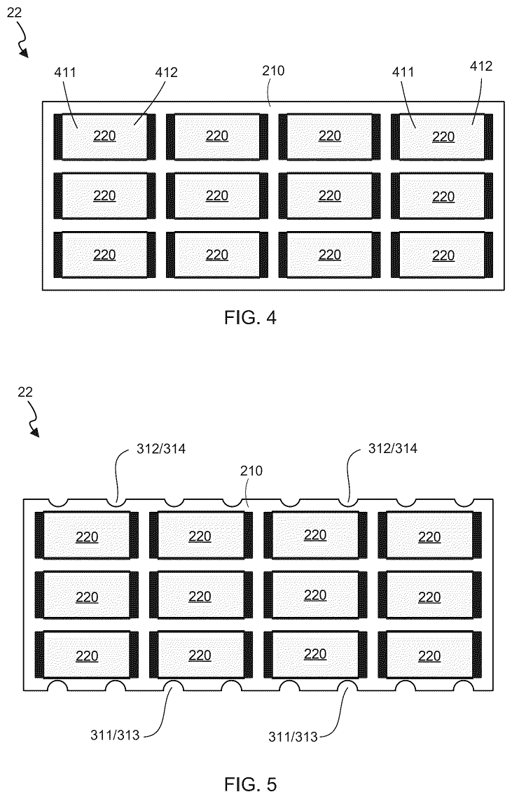

FIG. 4 shows the planar side view of the capacitor embedded connector 22 in accordance with an embodiment of the present invention. FIG. 4 represents a view in the direction of the arrow 323 shown in FIG. 3A and FIG. 3B (the substrate 240 and the optional molding compound 230 are shown as transparent). As shown in FIG. 4, each capacitor 220 has two pads 411 and 412. Pads 411 and 412 of each capacitor 220 are attached to the substrate 210, e.g., via soldering. In another embodiment, the pads 411 and 412 of each capacitor 220 are further attached to the substrate 240.

FIG. 5 shows the planar side view of the capacitor embedded connector 22 in accordance with another embodiment of the present invention. Side-wettable pads 311-314 can be flat or non-flat. As shown in FIG. 5, side-wettable pads 311-314 are half circle hole type. The side-wettable pads 311-314 could also be other type, e.g., half ellipse hole type, due to applications.

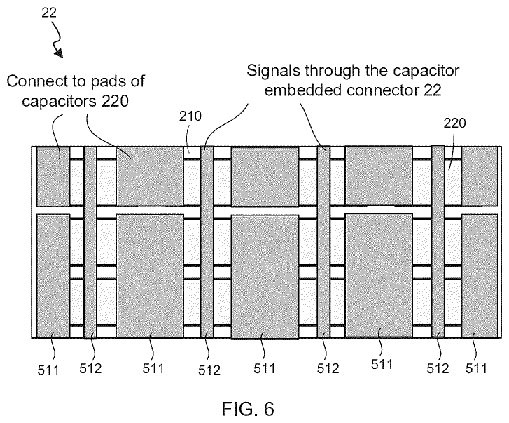

FIG. 6 shows a layout of the substrate 210 of the capacitor embedded connector 22 shown in FIG. 2 in accordance with an embodiment of the present invention. When using the capacitor embedded connector 22 to electrically connect the top substrate 203 to the base substrate 201, signals could pass through the capacitor embedded connector 22. As shown in FIG. 6, the capacitor embedded connector 22 has a plurality of interconnect structures 511 employed to connect to pads of capacitors 220, and the capacitor embedded connector 22 could further has a plurality of interconnect structures 512 to conduct signals, e.g., electrically connect nodes on the base substrate 201 to nodes on the top substrate 203. In one example, one of the interconnect structures 511 is configured to conduct the input voltage VIN between the top substrate 203 and the base substrate 201, another one of the interconnect structures 511 is configured to electrically connect the ground reference from the base substrate 201 to the top substrate 203. In one example, one of the interconnect structures 512 is configured to conduct the PWM signal from the base substrate 201 to the top substrate 203. In another example, the interconnect structures 512 is configured to conduct at least one of electrical signals (e.g., an enabling signal for enabling the pairs of high-side and low-side switches, a temperature monitoring signal for monitoring temperature of the power die 205, a current monitoring signal for monitoring current flowing through the high-side or the low-side switch, etc.) between the base substrate 201 and the top substrate 203.

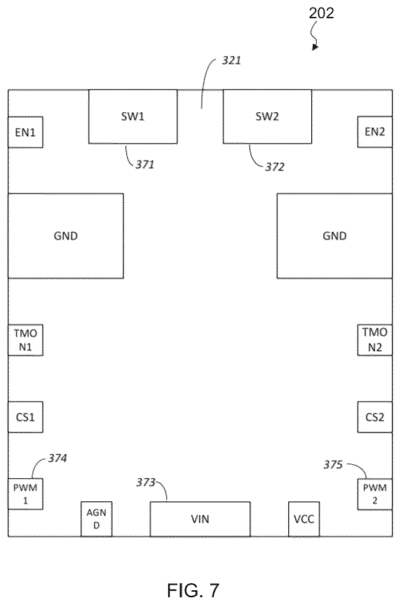

FIG. 7 shows a planar view of the top surface 321 of the inductor unit 202 in accordance with an embodiment of the present invention. FIG. 7 shows contact pads of the inductor unit 202 that interface with the bottom side of the top substrate 203, to electrically connect to corresponding nodes on the power die 205 via the top substrate 203.

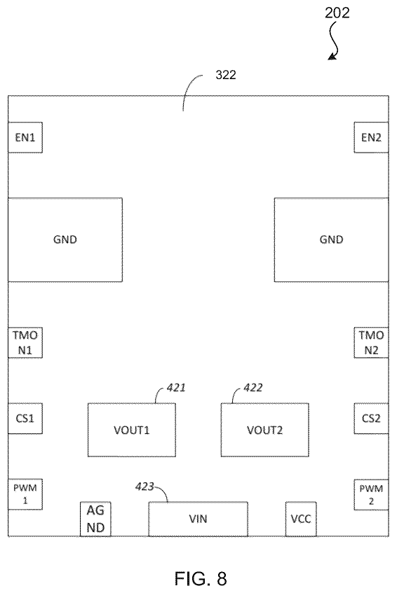

In the example of FIG. 7, a contact pad 371 electrically connects to a switch node (e.g., FIG. 2, SW1), a contact pad 372 electrically connects to another switch node (e.g., FIG. 2, SW2), a contact pad 373 electrically connects to the input voltage VIN, a contact pad 374 electrically connects to the gates of a pair of high-side and low-side switches, and a contact pad 375 electrically connects to the gates of another pair of high-side and low-side switches. In one embodiment, output inductors that are embedded within the inductor unit 202 have ends that are on opposite surfaces of the inductor unit 202. More particularly, an inductor that is embedded within the inductor unit 202 has a first end that is electrically connected to a switch node contact pad 371/372 on the top surface 321 and a second end that is electrically connected to an output voltage contact pad (e.g., FIG. 8, contact pad 421/422) on the bottom surface 322.

FIG. 7 also shows other contact pads, such as contact pads for enabling the pairs of high-side and low-side switches (“EN1”, “EN2”), contact pads for monitoring temperature (“TMON1”, “TMON2”), contact pads for monitoring current (“CS1”, “CS2”), contact pads for ground connections, contact pads for VCC, etc. Contact pads on the top surface 321 may electrically connect to contact pads on the bottom surface 322 by way of interconnect structures that that are attached to or embedded within the inductor unit 202. In another example, contact pads on the top surface 321 may electrically connect to contact pads on the bottom surface 322 by the capacitor embedded connector 22.

FIG. 8 shows a planar view of a bottom surface 322 of the inductor unit 202 in accordance with an embodiment of the present invention. FIG. 8 shows the bottom surface 322 of the inductor unit 202 as seen in the direction of the arrow 291 in FIG. 2 through the top substrate 203 and the inductor unit 202, i.e., as seen from the top with the substrate 310 and the rest of the inductor unit 202 being transparent.

FIG. 8 shows contact pads of the inductor unit 202 that interface with a topside of the bottom substrate 204 or a topside of the base substrate 201, to electrically connect to corresponding nodes on the base substrate 201, e.g., directly or via the bottom substrate 204. In the example of FIG. 8, a contact pad 421 electrically connects to an output voltage VOUT and to a second end of a first inductor (e.g., electrically connects to the output inductor 120-1 at node 122 shown in FIG. 1) that is embedded within the inductor unit 202, a contact pad 422 electrically connects to another output voltage VOUT and to a second end of a second inductor (e.g., electrically connects to the output inductor 120-2 at node 123 shown in FIG. 1) that is embedded within the inductor unit 202, a contact pad 423 electrically connects to the input voltage VIN. FIG. 8 also shows other contact pads that electrically connect to corresponding contact pads on the top surface 321 by way of interconnect structures that that are attached to or embedded within the inductor unit 202.

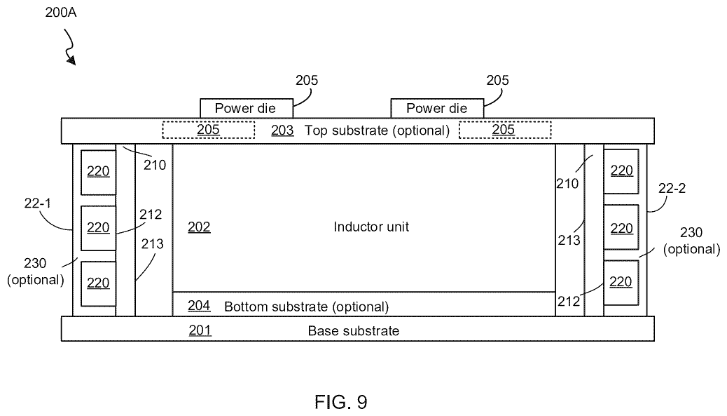

FIG. 9 shows a side view of a physical layout of a power converter 200A in accordance with an embodiment of the present invention. FIG. 9 is not drawn to scale. The power converter 200A is a particular embodiment of the power converter 200 of FIG. 2. In the example shown in FIG. 9, the power converter 200A comprises two capacitor embedded connectors 22 (i.e., 22-1, 22-2) vertically disposed on the base substrate 201. The inductor unit 202 is laterally disposed between two capacitor embedded connectors 22. Each capacitor embedded connector 22 has a substrate 210, a plurality of capacitors 220, and molding compound 230 (optional) filled in empty regions in each capacitor embedded connector 22. The plurality of capacitors 220 are attached to the first planar side 212 of the substrate 210, e.g., via soldering. The second planar side 213 of the substrate 210 faces towards the inductor unit 202. In the example of FIG. 9, the second planar side 213 of the substrate 210 of each capacitor embedded connectors 22 (i.e., 22-1, 22-2) faces towards the inductor unit 202. In one example, the capacitor embedded connectors 22 may be disposed along an outside perimeter of the top substrate 203 or along an outside perimeter of the base substrate 201. The capacitor embedded connectors 22 shown in FIG. 9 includes three capacitors in the vertical direction as one example, more or less capacitors may be included for different applications. In one example, the place that the capacitor embedded connectors 22 is disposed in is not limited by FIG. 9, the capacitor embedded connectors 22 can be disposed in other place of the module, such as the center area. In one embodiment, a power module may comprise two inductor units and three capacitor embedded connectors, one capacitor embedded connector is disposed in the center area, and two capacitor embedded connectors are disposed at two sides of the module.

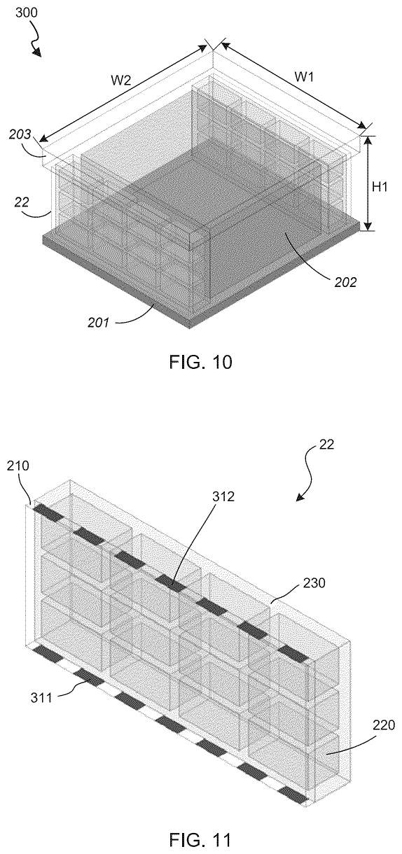

FIG. 10 shows a transparent three-dimensional (3D) view of a power module 300 in accordance with an embodiment of the present invention. The power module 300 is a particular embodiment of the power converter 200. FIG. 10 shows two capacitor embedded connectors 22 faces towards each other. In other examples, the power module 300 may comprises four capacitor embedded connectors 22 disposed around an outside perimeter of the power module 300.

As shown in FIG. 10, the power module 300 includes the base substrate 201, the capacitor embedded connectors 22, and the power block formed by the inductor unit 202, the top substrate 203 and one or more power dies 205 (not shown in FIG. 10, referring FIG. 9) embedded in or disposed on the top substrate 203. The quantity of the capacitors embedded in the capacitor embedded connectors 22 shown in FIG. 10 is just for illustration, more or less capacitors may also be included without detracting merits of the present invention. In one example, the power module 300 has a height H1 measured from a bottom surface of the base substrate 201 to a top surface of the top substrate 203 of at most 8 mm, typically 6 mm. The power module 300 has a width W1 of about less than 20 mm, typically 9 mm, and a length W2 of about less than 20 mm, typically 10 mm.

FIG. 11 shows a transparent 3D view of the capacitor embedded connector 22 of the power module 300 in accordance with an embodiment of the present invention. FIG. 11 shows the substrate 210, the plurality of capacitors 220, the molding compound 230, the plurality of side-wettable pads 312 on the top edge of the substrate 210, and the plurality of side-wettable pads 311 on the bottom edge of the substrate 210. In FIG. 11, the plurality of interconnect structures are omitted for illustration. The plurality of side-wettable pads 311 provides conductive paths, e.g., between the capacitor embedded connector 22 and the base substrate 201. The plurality of side-wettable pads 312 provides conductive paths, e.g., between the capacitor embedded connector 22 and the top substrate 203.

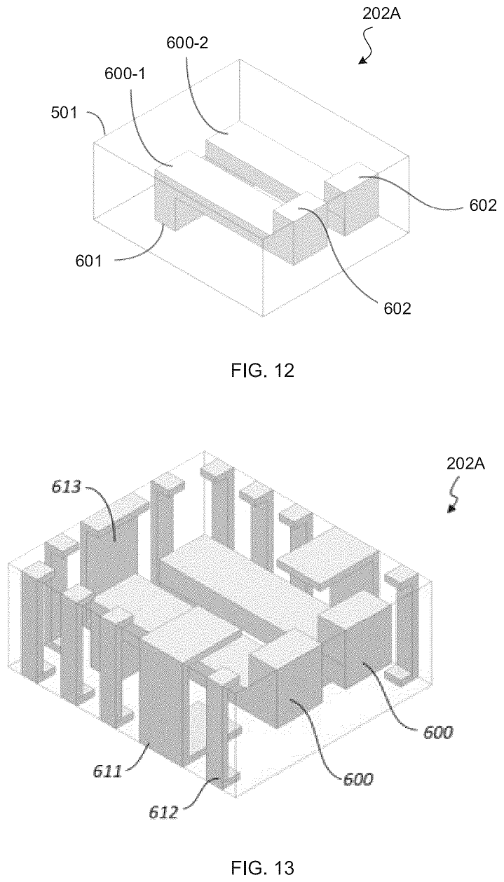

FIG. 12 shows a 3D transparent view of an inductor unit 202A in accordance with an embodiment of the present invention. The inductor unit 202A is an implementation of the inductor unit 202. The inductor unit 202A has two inductor windings 600 (i.e., 600-1, 600-2) embedded in a magnetic core 501. The inductor unit 202A is illustrated as having two inductors as one example, more windings may also be embedded in the magnetic core 501 to form more inductors in other examples. Each inductor winding has a first end 602 that is electrically connected to a contact pad on a top surface of the magnetic core 501 and a second end 601 that is electrically connected to a contact pad on a bottom surface of the magnetic core 501. In one embodiment, the top surface of the magnetic core 501 serves as a top surface of the inductor unit 202A, and the bottom surface of the magnetic core 501 serves as a bottom surface of the inductor unit 202A.

FIG. 13 shows additional 3D transparent view of the inductor unit 202A, in accordance with an embodiment of the present invention. As shown in FIG. 13, a plurality of Interconnect structures (e.g., 611, 612, 613) goes from the top surface to the bottom surface of the magnetic core 501. As an example, the interconnect structure 611 electrically connects a ground reference from a contact pad on the top surface (referring FIG. 7, GND contact pad) to a contact pad on the bottom surface (referring FIG. 8, GND contact pad) of the magnetic core 501. As another example, the interconnect structure 612 electrically connects an enable signal from a contact pad on the top surface (referring FIG. 7, EN contact pad) to a contact pad on the bottom surface (referring FIG. 8, EN contact pad) of the magnetic core 501. Yet another example, the interconnect structure 613 electrically connects the input voltage from a contact pad on the top surface (referring FIG. 7, contact pad 373) to a contact pad on the bottom surface (referring FIG. 8, contact pad 423) of the magnetic core 501.

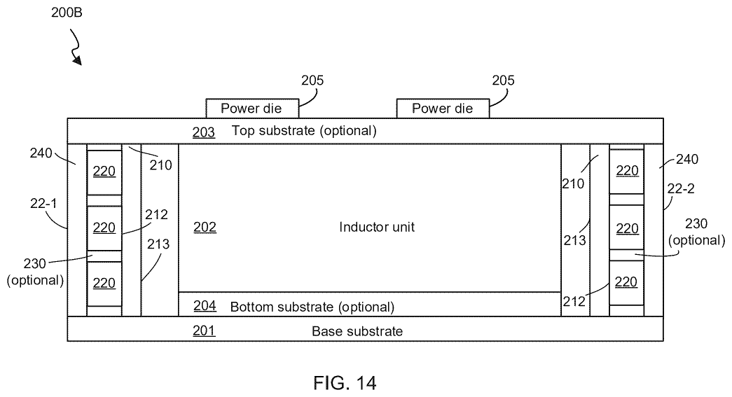

FIG. 14 shows a side view of a physical layout of a power converter 200B in accordance with an embodiment of the present invention. FIG. 14 is not drawn to scale. In the embodiment of FIG. 14, the capacitor embedded connector 22 further has the substrate 240 as described above for FIG. 3B. In another embodiment, the power dies 205 could be formed in the top substrate 203.

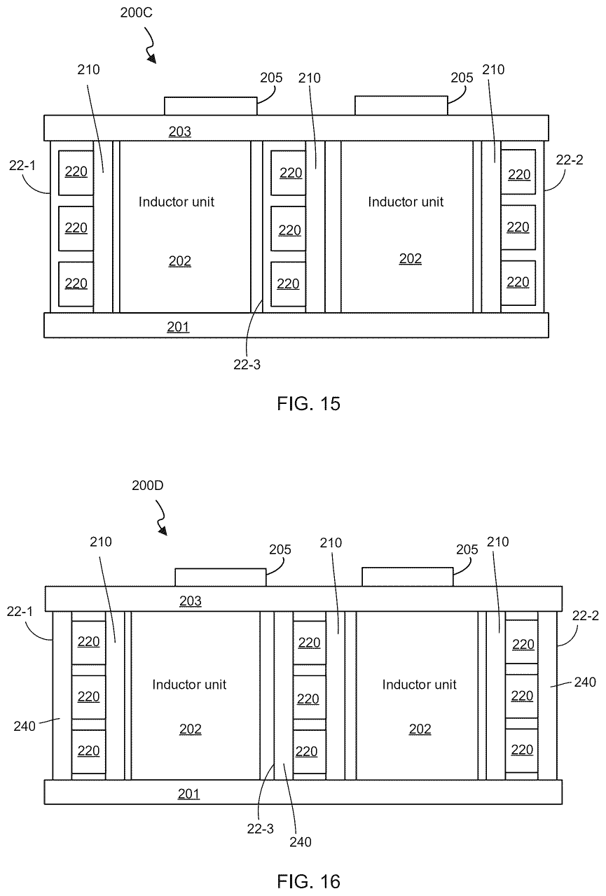

FIG. 15 shows a side view of a physical layout of a power converter 200C in accordance with an embodiment of the present invention. FIG. 15 is not drawn to scale. In the example shown in FIG. 15, the power converter 200C comprises three capacitor embedded connectors 22 (i.e., 22-1, 22-2, 22-3) and two inductor units 202. The capacitor embedded connector 22-3 is disposed in the center area, e.g., positioned between the two inductor units 202 as shown in FIG. 15. The capacitor embedded connectors 22-1 and 22-2 are disposed at two sides, e.g., the two inductor units 202 are laterally disposed between the capacitor embedded connectors 22-1 and 22-2. Detailed structure of the inductor units 202 refers to the inductor unit 202 shown in FIGS. 7-8, 12-13. Detailed structure of the capacitor embedded connectors 22 (i.e., 22-1, 22-2, 22-3) refers to the capacitor embedded connector 22 shown in FIG. 3A-3B, FIGS. 4-6, not limited by FIG. 15.

FIG. 16 shows a side view of a physical layout of a power converter 200D in accordance with another embodiment of the present invention. FIG. 16 is not drawn to scale. In the example shown in FIG. 16, the power converter 200D comprises three capacitor embedded connectors 22 (i.e., 22-1, 22-2, 22-3) and two inductor units 202. The capacitor embedded connector 22-3 is disposed in the center area, e.g., positioned between the two inductor units 202 as shown in FIG. 15. The capacitor embedded connectors 22-1 and 22-2 are disposed at two sides, e.g., the two inductor units 202 are laterally disposed between the capacitor embedded connectors 22-1 and 22-2. Detailed structure of the inductor units 202 refers to the inductor unit 202 shown in FIGS. 7-8, 12-13. Detailed structure of the capacitor embedded connectors 22 (i.e., 22-1, 22-2, 22-3) refers to the capacitor embedded connector 22 shown in FIG. 3A-3B, FIGS. 4-6, not limited by FIG. 16.

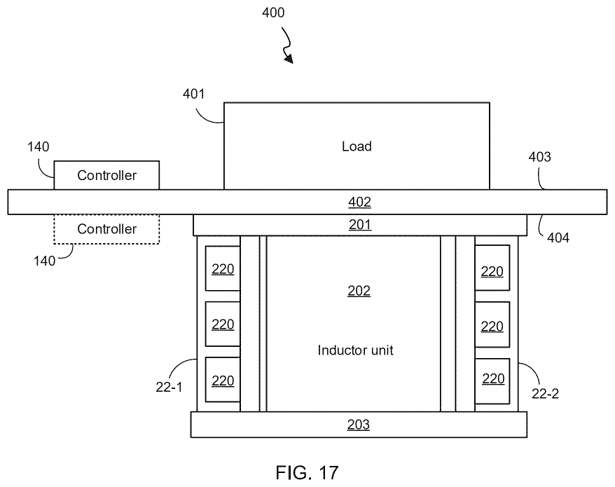

FIG. 17 shows a side view of a physical layout of a power supply system 400 in accordance with an embodiment of the present invention. FIG. 17 is not drawn to scale. In the example of FIG. 17, the power converter formed by the inductor unit 202 and the capacitor embedded connectors 22 provides power (e.g., an output voltage) to a load 401 (e.g., a CPU/GPU). The load 401 is disposed on a first side 403 of a motherboard 402, e.g., through associate socket and substrate. The inductor unit 202 and the capacitor embedded connectors 22 are disposed on a second side 404 of the motherboard 402. The second side 404 is opposite to the first side 403. In one example, the power converter is a power module, which further comprises the base substrate 201 and the top substrate 203 as shown in FIG. 17. The controller 140 may be placed on the first side 403 or on the second side 404. One or more power dies 205 may be formed in or attached to the top substrate 203 (not shown in FIG. 17).

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated, and they obviously will be resorted to by those skilled in the art without departing from the spirit and the scope of the invention as hereinafter defined by the appended claims as only a preferred embodiment(s) thereof has been disclosed.

What is claimed is:

1. A power converter, comprising:
a first power die and a second power die, each of the first and second power die has a gate driver and a pair of switches;
an inductor unit disposed on a base substrate, wherein the inductor unit has a first output inductor and a second output inductor, the first output inductor is electrically connected to a switch node formed by the pair of switches of the first power die, and the second output inductor is electrically connected to a switch node formed by the pair of switches of the second power die; and
a first connector vertically disposed on the base substrate, wherein the first connector comprises a first substrate, and a first plurality of capacitors attached to a planar side of the first substrate.

2. The power converter of claim 1, wherein the first connector further comprises:
a first side-wettable pad disposed on a bottom edge of the first substrate, to electrically connect the first connector to a first node on the base substrate.

3. The power converter of claim 2, wherein the first connector further comprises:
a second side-wettable pad disposed on a top edge of the first substrate, to electrically connect the first connector to a second node on a top substrate which is disposed on a top surface of the inductor unit.

4. The power converter of claim 1, wherein the first substrate further comprises:
a first interconnect structure electrically connected to pads of the first plurality of capacitors; and
a second interconnect structure electrically connecting a first node on the base substrate to a second node on a top substrate which is disposed on a top surface of the inductor unit.

5. The power converter of claim 1, wherein the first connector further comprises:
a second substrate perpendicular to the base substrate, wherein the first plurality of capacitors are soldered between the first substrate and the second substrate.

6. The power converter of claim 1, further comprising:
a second connector vertically disposed on the base substrate, wherein the second connector comprises a second substrate and a second plurality of capacitors attached to the planar side of the second substrate; and wherein
the inductor unit is disposed between the first connector and the second connector.

7. A power module, comprising:
a base substrate;
a first pair of switches and a second pair of switches;
a first inductor unit disposed on the base substrate, comprising a magnetic core, a first winding and a second winding embedded in the magnetic core, wherein the first winding is electrically connected to a first switch node formed by the first pair of switches, and the second winding is electrically connected to a second switch node formed by the second pair of switches;
a top substrate disposed on the first inductor unit; and
a first connector and a second connector, vertically disposed between the base substrate and the top substrate, wherein each of the first and second connectors has a first substrate, and a first plurality of capacitors attached to the first substrate.

8. The power module of claim 7, wherein the first connector and the second connector are disposed along an outside perimeter of the power module.

9. The power module of claim 7, wherein the first inductor unit is disposed between the first connector and the second connector.

10. The power module of claim 7, wherein the first substrate has an interconnect structure electrically connecting a first node on the top substrate to a second node on the base substrate.

11. The power module of claim 7, wherein the first substrate has a first interconnect structure electrically connected to pads of the first plurality of capacitors, and a second interconnect structure electrically connecting a first node on the top substrate to a second node on the base substrate.

12. The power module of claim 7, wherein each of the first and second connectors further comprises:
a first side-wettable pad disposed on a bottom edge of the first substrate, to electrically connect to a first node on the base substrate; and
a second side-wettable pads disposed on a top edge of the first substrate, to electrically connect to a second node on the top substrate.

13. The power module of claim 7, further comprising:
a second inductor unit disposed on the base substrate;
a third connector vertically disposed between the base substrate and the top substrate, wherein the third connector has a second plurality of capacitors; wherein
the first inductor unit and the second inductor unit are disposed between the first connector and the second connector, the third connector is disposed between the first inductor unit and the second inductor unit.

14. The power module of claim 7, wherein the first pair of switches and the second pair of switches are formed in the top substrate.

15. The power module of claim 7, wherein the power module has a height measured from a bottom surface of the base substrate to a top surface of the top substrate of at most 8mm.

16. The power module of claim 7, wherein each of the first and second connector further comprises:
a second substrate perpendicular to the base substrate, wherein the first plurality of capacitors are soldered between the first substrate and the second substrate.

17. A power converter operable to provide an output voltage to a load which is disposed on a first side of a motherboard, the power converter comprising:
an inductor unit disposed on a second side of the motherboard which is opposite to the first side of the motherboard, wherein the inductor unit has an output inductor, a first end of the output inductor is electrically connected to a switch node formed by a pair of switches, and a second end of the output inductor is electrically connected to the load; and
a first connector vertically disposed on the second side of the motherboard, wherein the first connector comprises a first substrate which is perpendicular to the motherboard, and a first plurality of capacitors attached to the first substrate.

18. The power converter of claim 17, wherein the first connector further comprises:
a first side-wettable pad disposed on a bottom edge of the first substrate, to electrically connect the first connector to a first node on a base substrate.

19. The power converter of claim 18, wherein the first connector further comprises:
a second side-wettable pad disposed on a top edge of the first substrate, to electrically connect the first connector to a second node on a top substrate which is disposed on the inductor unit.

20. The power converter of claim 17, wherein the first substrate further comprises:
a first interconnect structure electrically connecting to pads of the first plurality of capacitors; and
a second interconnect structure providing conduct path between a base substrate and a top substrate which is disposed on the inductor unit.

21. The power converter of claim 17, further comprising:
a second connector vertically disposed on the motherboard, the second connector comprising a second substrate which is perpendicular to the motherboard, and a second plurality of capacitors attached to the second substrate; wherein
the inductor unit is disposed between the first connector and the second connector.
